(19) United States
(12) Patent Application Publication
(10) Pub. No.: US 2016/0071791 A1
(43) Pub. Date: Mar. 10, 2016

(54) MULTIMETAL INTERLAYER INTERCONNECTS

(71) Applicant: GLOBALFOUNDRIES INC., Grand Cayman (KY)

(72) Inventors: Elbert E. Huang, Carmel, NY (US); David L. Rath, Stormville, NY (US); Wei-tsu Tseng, Hopewell Junction, NY (US)

(21) Appl. No.: 14/480,718

(22) Filed: Sep. 9, 2014

(51) Int. Cl. H01L 23/528; H01L 21/3213; H01L 21/768; H01L 21/321; H01L 27/088; H01L 23/532

(52) U.S. Cl. CPC H01L 23/528; H01L 27/0886; H01L 23/53238; H01L 21/76807; H01L 21/76877; H01L 21/76843; H01L 21/7684; H01L 21/3212; H01L 21/32133

(57) ABSTRACT

A set of trenches can be formed in a thin film dielectric layer located on a substrate. The set of trenches can be filled with a predominantly tungsten layer that electrically connects circuit components located on the substrate. The tungsten layer can be recessed below an upper surface of the thin film dielectric layer, while maintaining electrical connection between the circuit components located on the substrate. A liner can be formed over the tungsten layer in the trenches. A metal layer that is predominantly made from a metal other than tungsten, can be formed over the liner.

### BACKGROUND

The present disclosure relates to multi-metal interconnections, and more specifically, to multi-metal interconnections created near a semiconductor substrate.

Semiconductor devices can include a semiconductor substrate, which can include doped silicon, and a plurality of sequentially formed interlayer dielectrics and interconnected metallization layers defining conductive patterns. An integrated circuit can be formed from a plurality of conductive patterns including conductive lines separated by an insulator, and a plurality of interconnect lines, such as bus lines, bit lines, word lines and logic interconnect lines. The conductive patterns on different metallization layers can be electrically connected by vias, and contact openings can allow electrical connection to electrical components on a semiconductor substrate, such as a source or drain region of a transistor.

### SUMMARY

Various embodiments are directed toward a method for forming local interconnections between electrical contacts on a substrate. The method can includes forming, as a part of middle of line process, a set of trenches between the electrical contacts and in a thin film dielectric layer that is located on the substrate. The set of trenches can be filled with a predominantly tungsten layer that electrically connects circuit components located on the substrate. The tungsten layer can be recessed below an upper surface of the thin film dielectric layer, while maintaining electrical connection between the circuit components located on the substrate. A liner can be formed over the tungsten layer in the trenches. A metal layer that is predominantly made from a metal other than tungsten can be formed over the liner.

Various embodiments are directed toward an integrated circuit device that includes a substrate; a plurality of electrical components on the substrate; a thin film dielectric layer on the substrate; and a set of interconnections electrically connecting the electrical components, each interconnection formed within a respective trench in the thin firm dielectric layer and having: a predominantly tungsten layer extending between two electrical components of the plurality of electrical components; a liner over the tungsten layer and extending between the two electrical components; and a metal layer that is over the tungsten layer, extends between the two electrical components and is predominantly made from a metal other than tungsten.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

FIG. 1 depicts a flow diagram for a process of creating multi-metal interconnect lines for an integrated circuit chip, consistent with embodiments of the present disclosure;

FIG. 2 depicts a semiconductor structure with a trench in a dielectric layer, consistent with embodiments of the present disclosure;

FIG. 3 depicts a semiconductor structure with a trench filled with metal, consistent with embodiments of the present disclosure;

FIG. 4 depicts a semiconductor structure with metal in trenches having been recessed, consistent with embodiments of the present disclosure;

FIG. 5 depicts a semiconductor structure with a liner over recessed metal, consistent with embodiments of the present disclosure;

FIG. 6 depicts a semiconductor structure with a second, upper metal atop the recessed metal, consistent with embodiments of the present disclosure;

FIG. 7 depicts a semiconductor structure with a portion of a second, upper metal removed, consistent with embodiments of the present disclosure;

FIG. 8 depicts an isometric diagram for interconnection wires that can be within a semiconductor device, consistent with embodiments of the present disclosure;

FIG. 9 depicts a device that includes Fin Field-Effect-Transistors (finFETs) and local interconnections, consistent with embodiments of the present disclosure; and

FIG. 10 depicts a top down view of a device with finFETs, consistent with embodiments of the present disclosure.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention.

### DETAILED DESCRIPTION

Aspects of the present disclosure relate to multi-metal interconnects, more particular aspects relate to a multi-metal interconnects within an interlayer dielectric. While the present disclosure is not necessarily limited to such applications, various aspects of the disclosure may be appreciated through a discussion of various examples using this context.

Embodiments of the present disclosure are directed toward a semiconductor device in which interconnection lines within an interlayer dielectric connect electrical components located on (or within) a substrate. Particular embodiments include interconnection lines that have a lower portion made from a conductive metal that has a relatively low susceptibility to diffusion through the interlayer dielectric (e.g., tungsten) and an upper portion made from a different conductive metal that has a higher susceptibility to diffusion through the interlayer dielectric (e.g., copper).

Particular embodiments are directed toward the creation of multi-metal interconnection lines during middle of line (MOL) processing of a semiconductor device. The multi-metal interconnection lines can run substantially parallel to the substrate and include a lower layer of metal that is configured to server as a barrier that prevents back end of line (BEOL) materials and processes to contaminating the front end of line (FEOL) devices. For example, some wet chemistries that might be used for BEOL the fabrication of subsequently applied metal wiring could damage the underlying W/TiN/Ti metallization. As used herein, an FEOL processes can include wafer preparation, isolation, well formation, gate patterning, spacer, extension and source/drain implantation, silicide formation, and dual stress liner formation. For example, the MOL process can include gate contact (CA) formation for a three dimensional (3D) Fin Field-Effect-Transistor (FinFET).

As discussed herein, the use of the copper containing cap atop the tungsten metal wiring level can effectively protect this level from wet chemistries used in the BEOL process. Moreover, various embodiments can include the use of a liner for the copper cap, which can provide benefits for tungsten seam filling/coverage. In particular the liner can be made thicker than what is often used during the BEOL, without negatively impacting resistances of the tungsten metal wiring level. The improvement in Tungsten seam filling/coverage can be useful for protecting against issues related to the encapsulation of wet chemistries (e.g, copper plating chemistry) in the seams. For example, a keyhole shaped seam can form between a liner for the tungsten and the walls of the trench. The use of another liner for the copper can partially or completely seal such seams.

As discussed herein, local interconnections can use an upper layer of metal that provides better transmission characteristics, and in particular, lower resistance relative to the lower layer of metal. The two layers of metal in the interconnection lines effectively function as parallel resistive paths, and as such, the lower resistance of the upper metal can dominate the overall resistance of the interconnection lines. Accordingly, the effective resistance of the local interconnection lines can be relatively low due to the use of metals that would otherwise not be suitable for use in the FEOL process (e.g., due to diffusion problems that can result in device formation through copper silicide formation).

Consistent with various embodiments, high performance applications (e.g., microprocessor applications) may demand rapid speed of semiconductor circuitry. The speed of semiconductor circuitry can vary inversely with the resistance and capacitance of the interconnections between electrical components. In particular, with smaller feature sizes and spacing for integrated circuits, the integrated circuit speed becomes less dependent upon the active (transistor) components and more dependent upon the interconnections. For example, smaller spacing and features sizes may result in smaller contacts and interconnection line cross-sections, reducing the effective resistance of the interconnection line. While a material such as tungsten can be used as a barrier between BEOL processes and the FEOL devices, tungsten has a relatively high resistivity when compared to other materials commonly used for interconnects, such as copper, aluminum, and silver.

Various embodiments are directed toward semiconductor device that includes electrical interconnects that can use copper. Copper (Cu) is relatively inexpensive, easy to process, has a lower resistivity than tungsten (W), and has improved electrical properties in comparison to tungsten. Aspects of the present disclosure, however, are based upon the recognition that copper can diffuse through the inter-dielectric layer, which in some instances can be a thin film layer of less than 40 nm.

Some embodiments relate to semiconductor devices that include FinFETs that are connected by multilayer metal interconnections in an interlayer dielectric. In certain embodiments, the FinFETs can be located on a silicon-on-insulator (SOI) structure.

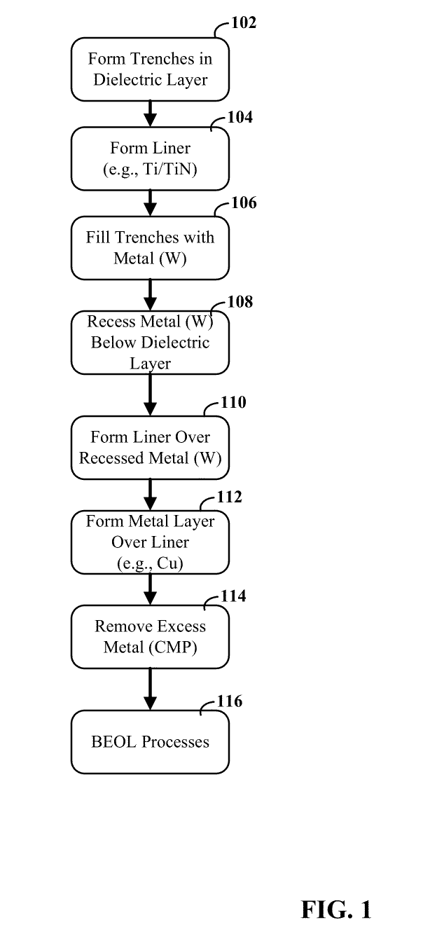

Turning now to the figures, FIG. 1 depicts a flow diagram for a process of creating multi-metal interconnect lines for an integrated circuit chip, consistent with embodiments of the present disclosure. In embodiments of the present disclosure, the process can be applied after an FEOL process that creates a substrate with electrical components (e.g., transistors) and a dielectric layer. Trenches and vias can then be formed within the dielectric layer, per block 102. As discussed herein, the trenches can extend between contact points of difference electrical components on the substrate (e.g., between contact points of the source/drain contacts of different FinFETs and/or contact points of the gates) and run parallel to the substrate. The vias run vertical relative to the substrate and serve as connections between conducting levels. As discussed herein, the components located on the substrate may include FinFET devices; however, other electrical/logic components can also be connected using the trenches.

In some embodiments, a first liner can be formed within the trenches for use with a first metal (e.g., tungsten), per block 104. For example, the liner could be a thin titanium/titanium nitride (Ti/TiN) bilayer. Whether or not this first liner is used, the trenches can then be filled with a metal, such as tungsten (W), per block 106. In some embodiments, after tungsten filling of the trenches, chemical mechanical polishing (CMP) process can be employed to remove the top portion of the tungsten, while the CMP process is halted at the first liner. In various embodiments, the CMP process can remove a portion of the tungsten and also remove some, or all, of the first liner. The tungsten metal can then be recessed within the trenches to a level that is below the upper surface of the dielectric layer, per block 108. In some embodiments, the CMP process can remove a portion of the dielectric during the polishing of the tungsten. Various embodiments allow for the first liner to be removed from the sidewall of the trench at a depth that equals, or is less than, the recess depth of the tungsten metal.

According to embodiments, a second liner can be formed over the recessed metal and along the trench walls for use with a second metal (e.g., copper), as shown by block 110. As discussed herein, the trench walls may still contain the first liner resulting in a dual liner at these locations. In other instances, the first liner may have been removed during the CMP process. A metal layer, of different material than the recessed metal (e.g., copper), can then be formed over the second liner and within the trenches, per block 112. Excess metal can then be removed, per block 114. The formation of the remainder of the semiconductor device can then be completed including BEOL processes, per block 116.

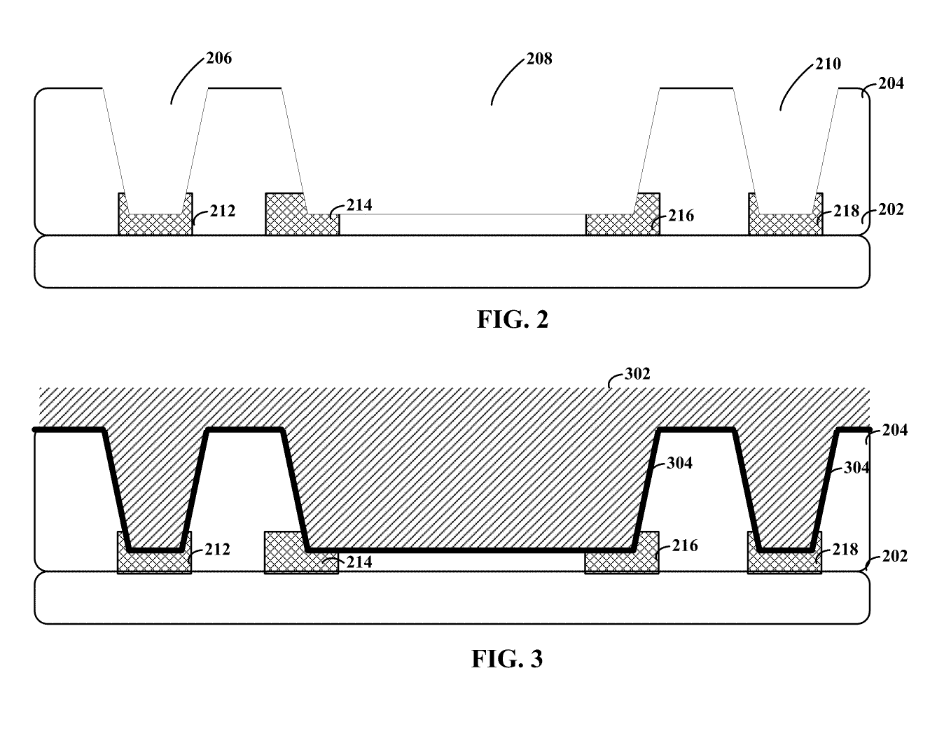

FIGS. 2-7 depict semiconductor structures at different stages in a manufacturing process, such as the process described in connection with FIG. 1.

FIG. 2 depicts a semiconductor structure with a trench in a dielectric layer, consistent with embodiments of the present disclosure. According to embodiments, a dielectric layer 204 can be formed on a substrate 202. Although not depicted, there can be one or more layers between the dielectric layer 204 and the substrate 202, including patterning layers and etch stop layers. Additionally a number of electrical devices, and their components, can be formed as part of the semiconductor substrate 202, for example, these devices may include gate structures as part of a FinFET device. A trench 208 can be formed within the dielectric layer 204 between the electrical components 214, 216 (e.g., gate contacts/structures) located on (or in) the substrate either end of the trench 208. Consistent with various embodiments, the trench 208 can form a line between contacts (or terminals) of electrical components, such as the gate, source or drain of a transistor positioned in the underlying substrate 202. One or more vias 206, 210 can also be created within the dielectric layer 204 to connect to contacts for electrical components 212, 218.

The substrate 202 can include a number of electrical components (e.g., active components, passive components, and combinations thereof), which can be located within the substrate 202 or on a surface thereof. In certain embodiments, the substrate 202 can be made from any one of a variety of different semiconductor materials, such as type IV or III/V compound semiconductors that can include, but are not necessarily limited to, Si, SiGe, SiC, SiGeC, InAs, GaAs, InP and Ge. The substrate 202 can be undoped, or doped.

According to embodiments, the dielectric layer 204 is designed to be used as an interlayer dielectric and can be formed atop the substrate 202 using a deposition process, such as spin-on coating, plasma enhanced chemical vapor deposition (PECVD), evaporation, or chemical solution deposition. The dielectric layer 204 can include insulating materials that include, but are not limited to, various oxides (e.g., SiO₂), and low-k carbon doped oxide layers (e.g., SiCOH).

Consistent with certain embodiments, the trench and vias (or just “openings”) 206, 208, 210 in the dielectric layer 204 can expose portions of the underlying substrate 202. In certain embodiments a lithographic etching process can be used to create the openings 206, 208, 210. For example, a photoresist can be used to pattern the dielectric layer 204 to allow for selective etching that can form the openings 206, 208, 210.

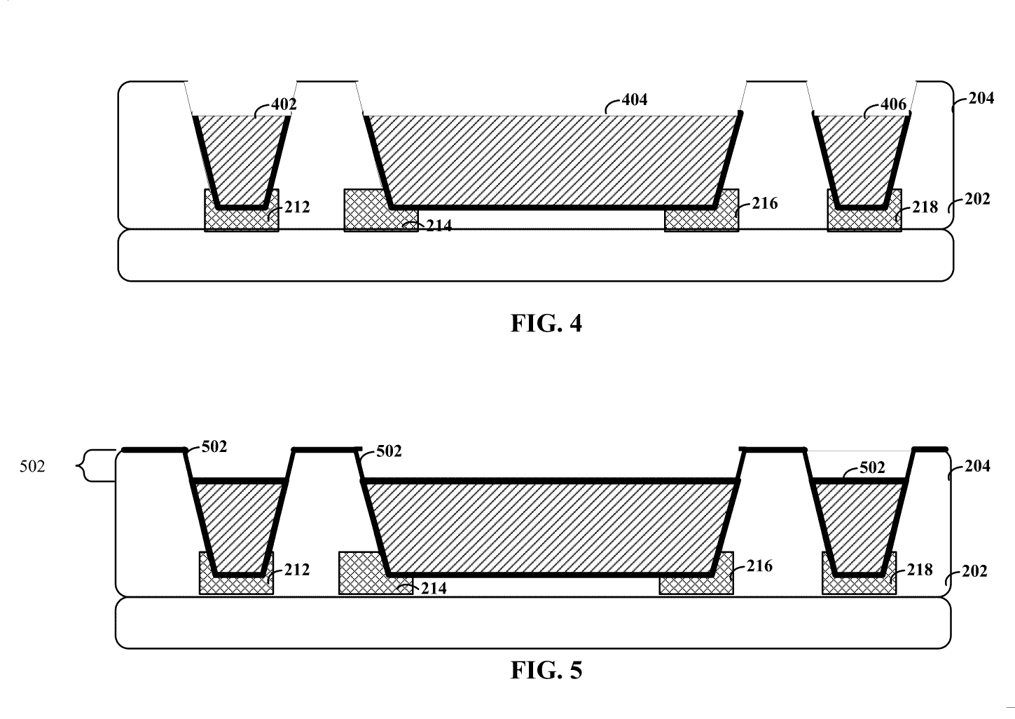

FIG. 3 depicts a semiconductor structure with a trench filled with metal, consistent with embodiments of the present disclosure. Consistent with various embodiments, a metal 302, such as tungsten (W), can be formed within the openings in the dielectric layer 204. Consistent with embodiments, the first metal can be predominantly tungsten. In various embodiments, the first metal can be almost entirely tungsten, although it may contain some impurities. As discussed herein, the metal 302 can become the first metal of the multi-metal interconnection lines. For example, a tungsten layer can be formed using a physical vapor deposition process, such as plating or sputtering. In certain embodiments, a planarization process, such as chemical-mechanical polishing or grinding, can be used to create a planar upper surface, as depicted in FIG. 3. If a planarization process is implemented, it can be done to polish down to the interlayer dielectric 204. Alternatively, it can be done in a fashion that polishes down to a first liner 304.

Consistent with embodiments, the first liner 304 can be created between the metal 302 and the dielectric layer 204. The first liner 304 can include a metal nitride including, but not necessarily limited to, titanium (Ti), titanium nitride (TiN), tantalum, tantalum nitride (TaN), tantalum aluminum nitride (TaAlN), tungsten nitride (WN), tungsten silicon nitride (WSiN), titanium aluminum nitride (TiAlN), cobalt (Co), ruthenium (Ru), and combinations thereof. For example, the first liner 304 may include a titanium (Ti) layer atop the substrate 202, and a titanium nitride (TiN) layer atop the titanium (Ti) layer. Consistent with embodiments, the first liner 304 can be deposited by atomic layer deposition, physical vapor deposition, or by chemical vapor deposition.

FIG. 4 depicts a semiconductor structure with metal in trenches having been recessed, consistent with embodiments of the present disclosure. According to embodiments, the upper surface of the metal (e.g., tungsten) can be recessed below the dielectric layer 204 at locations 402, 404 and 406. The recessing can be carried out using one of a variety of etch processes. For example, a peroxide containing wet clean or strong oxidizing acid such as aqua regia may be used recess W and Ti/TiN liner. Alternatively, a reactive ion etch process involving NF3, C12, BC13 may be used. While FIG. 4 depicts the first liner 304 as having been partially removed, various embodiments allow for some, or all, of the first liner 304 to remain in the portions of the trench where the tungsten was removed.

Consistent with embodiments, the upper surface of the metal (tungsten) can be recessed 10 nm to 200 nm from the upper surface the dielectric layer 204. In other embodiments, the upper surface of the metal is recessed 30 nm to 100 nm from the upper surface the dielectric layer 204. In a various embodiments, the upper surface of the metal is recessed 20 nm to 50 nm from the upper surface of the dielectric layer 204. The amount of recess can be selected based upon the ability to maintain the protective qualities provided by the tungsten, while providing better signal qualities (e.g., lower resistance) due to more of the second metal (e.g., Cu). Thus, the amount of recess can be used to set the ratio of the two metals at a desirable level, without removing too much of the protective tungsten layer (e.g., maintaining electrical connection between the electrical components and providing sufficient protection from copper diffusion, wet chemistries, or other problems). For example, the copper height relative to the tungsten height, within the trench, can be selected to achieve ratios that are between 10:1 and 1:10. More particular ratios can allow for a range of 5:1 and 1:5. In some embodiments, the ratio can be 1:1. Other ratios and ranges are also possible.

In some embodiments, the structure depicted in FIG. 4 may suffer from seams that can form along the center of the trench and run parallel to the trench. In particular, the seams may form because the tungsten deposition process does not fill the trenches well. This may complicate the formation of other metal features that would otherwise land on this metal trench. As discussed herein, subsequently applied liner layers can be useful for partially, or completely, sealing such seams.

FIG. 5 depicts a semiconductor structure with a liner over recessed metal, consistent with embodiments of the present disclosure. According to various embodiments, a second, conductive liner 502 can be created over the recessed metal and sidewalls of the openings in the dielectric material 204. For example, if the upper metal material is to be copper, then the second liner 502 can be made from tantalum nitride, tantalum, ruthenium, cobalt, manganese and combinations thereof. A particular example is a tantalum nitride layer upon which a tantalum layer rests. In embodiments where the liner 304 is still present after the etching of the tungsten, the resulting structure can include a dual layer liner (e.g., Ti/TiN beneath TaN/Ta) along the sidewalls of the upper portion of the trench (indicated by the bracket 502). A metal (e.g., copper) seed layer may then be deposited (e.g., using sputtering) atop the tantalum (Ta) layer.

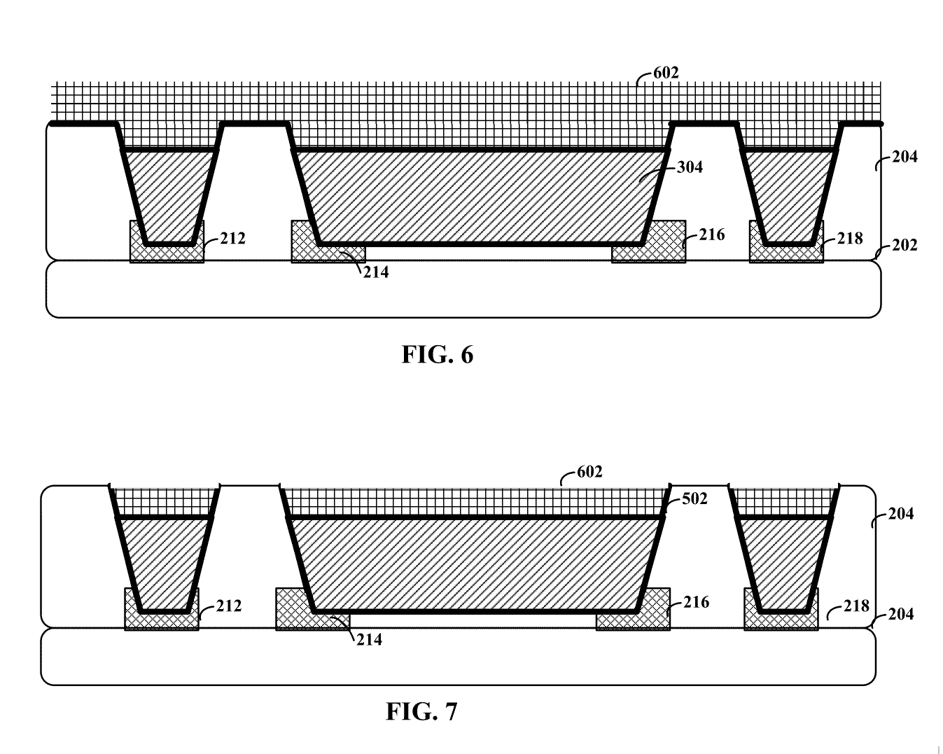

FIG. 6 depicts a semiconductor structure with a second, upper metal atop the recessed metal, consistent with embodiments of the present disclosure. According to various embodiments, an upper metal material 602 (e.g., copper (Cu)) can be deposited by one or a combination of different processes including: physical vapor deposition, chemical vapor deposition, or electroplating (e.g., using a seed layer in the liner 502). As discussed herein, the upper metal 602 along with the lower metal 304 can form the multi-metal interconnection lines. Moreover, the ratio of the upper metal 602 to the lower metal 304 can be controlled according to the depth of the recess and the amount of the second metal that is removed in the subsequent process step.

Consistent with various embodiments, the upper metal material 602 can be deposited using a dual-damascene processes that can fill multiple features as part of the same process. For instance, both the trench 208 and vias 206, 201 can be filled as part of a single copper deposition process.

FIG. 7 depicts a semiconductor structure with a portion of a second, upper metal removed, consistent with embodiments of the present disclosure. A planarization process (e.g., a suitable chemical-mechanical planarization process) can then be applied to the upper metal material 602 and a portion of the dielectric layer 204 can be removed during this process. After planarization process the upper metal material 602 (e.g., copper) is approximately even with the upper surface of the remaining dielectric layer 204.

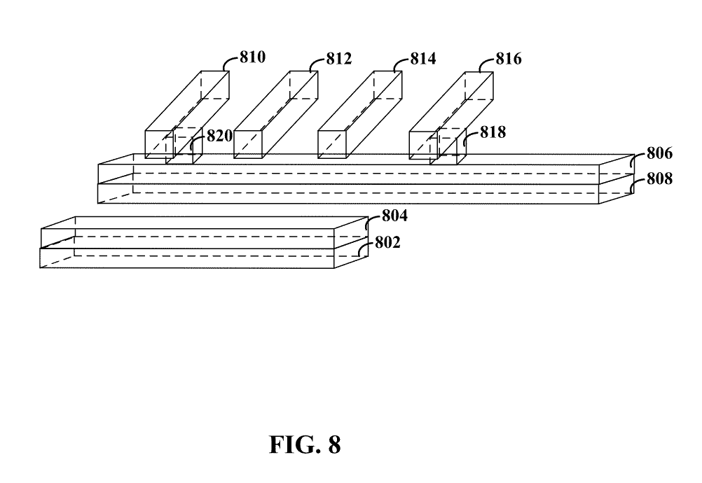

FIG. 8 depicts an isometric diagram for interconnection wires that can be within a semiconductor device, consistent with embodiments of the present disclosure. A first interconnection is depicted by multi-metal layers 802 and 804. As discussed herein, this interconnection can be located on an interlayer dielectric (not shown) that is close to the semiconductor substrate (not shown). This interconnection can be used to electrically connect components that are located on, or in, the semiconductor substrate and can correspond to the multi-metal interconnection lines discussed in connection with FIGS. 1-7.

Multi-metal layers 806 and 808 depict a second interconnection that can also connect electrical components that are located on the semiconductor substrate. Moreover, one or more vias 818, 820 can connect to an upper layer of interconnections 810 and 816 (sometimes referred to as the M1 or M2 layers). In this manner, direct connections to components on the substrate can be made using multi-metal layers 806 and 808, while at the same time, connections can be made to other routing layers. Vias 818, 820 can be selectively used to connect to different upper layer interconnects. For example, M1 interconnects 812 and 814 are depicted as not being connected to the interconnection formed by multi-metal layers 806.

In certain embodiments, the M1 interconnects can be made from the same material used in the upper layers 802, 806 of the multi-layer interconnections. For example, they can each use copper as the primary material. In other embodiments, different metals can be used.

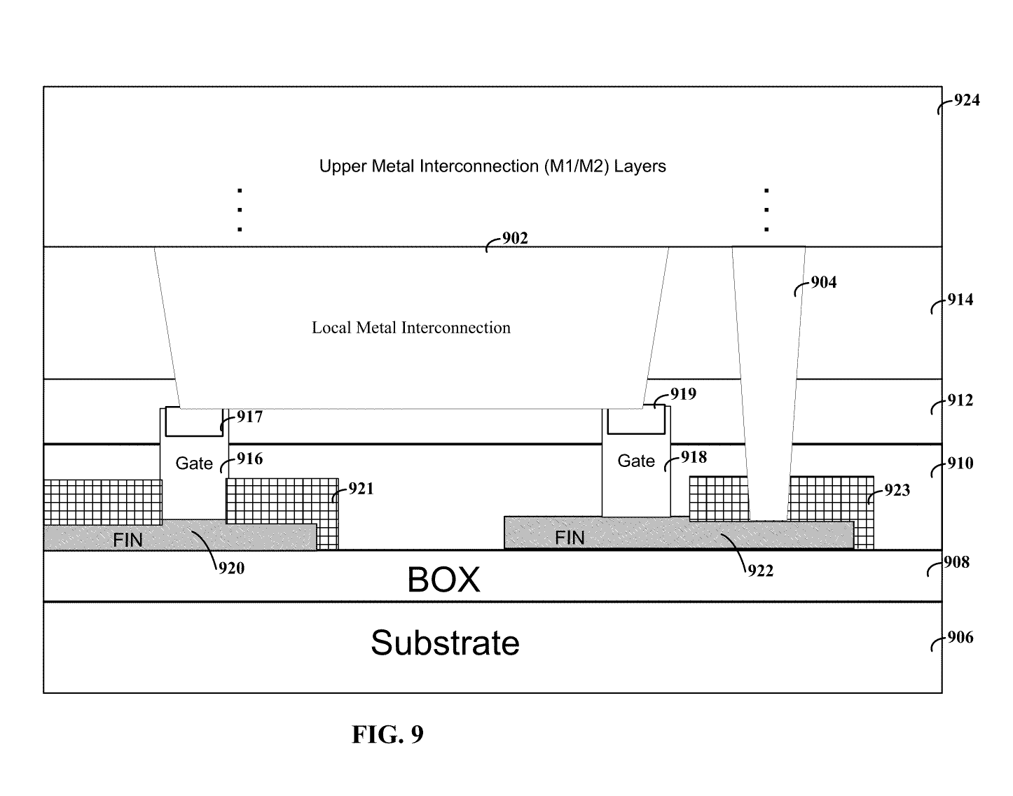

FIG. 9 depicts a device that includes finFETs and local interconnections, consistent with embodiments of the present disclosure. The FEOL process can include the creation of layers 906-912 and various electrical components. For example, the device can include a substrate 906 and buried oxide (BOX) layer 908. One or more fins 920, 922 for the FETs can be created within dielectric layer 910. Gate structures 916, 918 can provide contact points for local bimetal interconnections 902.

As discussed herein, the local bimetal interconnections 902 can be formed within a thin film dielectric layers 912 and 914 and provide electrical connection between electrical components, such as between gates 916 and 918. More particularly, the local bimetal interconnections 902 can provide electrical connection between contacts 917 and 919. Moreover, the device can include one or more vias 904. In embodiments, both the local bimetal interconnections 902 and the vias 904 can include dual metal layers (e.g., a lower layer of tungsten and upper layer of copper). Moreover, they can both be created during the same set of process steps (e.g., as part of a single a dual damascene process).

Consistent with embodiments, the local metal interconnections 902 can serve as local interconnections between components, while the vias can be connected to upper metal interconnection layers (e.g., M1/M2 layers) 924.

Consistent with embodiments, a plurality of finFET transistors can be formed on a substrate and a buried oxide layer (BOX). The finFET transistors can include silicon fins 920, 922 of around 25 nm (+/−2.5) nm in height and a doped region 921, 923. A gate 916, 918 can have a height of about 47 nm (+/−8 nm). The total interlayer dielectric layer (before silicide processing) can have a height of around 82 nm (+/−15 nm). A layer of SiN can be located in middle of the line (MOL) and have a thickness of approximately 20 nm (+/−2 nm).

According to embodiments, the multi-metal interconnections can be formed in trenches of about 20 nm (+/−7 nm) in width at their bottom. Contact vias connecting to these multi-metal interconnections can extend through the dielectric and have a width that the top of the dielectric of about 30 nm (+/−6 nm).

The above dimensions are provided as examples in a particular example of finFET components. Other dimensions and configurations are possible.

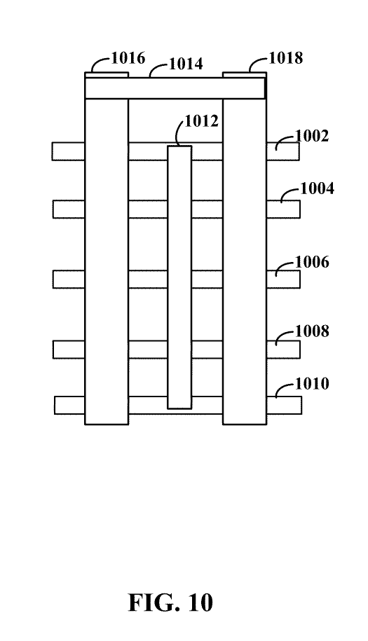

FIG. 10 depicts a top down view of a device with finFETs, such as the device from FIG. 9, consistent with embodiments of the present disclosure. Consistent with embodiments, a set of fins 1002-1010 can be connected by a local bimetal interconnect 1012. In various embodiments, additional local bimetal interconnects can also be created within the device. For example, a local bimetal interconnect 1014 can connect two or more gates 1016 and 1018.

The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

What is claimed is:

1. A method for forming local interconnections between electrical contacts on a substrate, the method comprising:
forming, as a part of middle of line process, a set of trenches between the electrical contacts and in a thin film dielectric layer that is located on the substrate;
filling the set of trenches with a predominantly tungsten layer that electrically connects circuit components located on the substrate;
recessing the tungsten layer below an upper surface of the thin film dielectric layer, while maintaining electrical connection between the circuit components located on the substrate;
forming a liner over the tungsten layer in the trenches; and
forming, over the liner, a metal layer that is predominantly made from a metal other than tungsten.

2. The method of claim 1, wherein the metal other than tungsten is copper and wherein forming, over the liner, a metal layer that is predominantly made from a metal other than tungsten includes the use of a dual damascene process during which copper is deposited within at least one via in the thin film dielectric layer.

3. The method of claim 1, further comprising forming, before filling the set of trenches, a bilayer titanium/titanium nitride liner in the trenches.

4. The method of claim 3, further comprising a liner that is on a portion of a sidewall of the trenches above the tungsten layer and that includes a Ti-TiN layer beneath a TaN-Ta layer.

5. The method of claim 3, wherein recessing the tungsten layer includes removing the bilayer titanium/titanium nitride liner from a portion of the trenches that is above the recessed tungsten layer.

6. The method of claim 1, wherein the liner is predominantly made from tantalum nitride.

7. The method of claim 1, further comprising removing, using a chemical mechanical polishing (CMP) process, a portion of the tungsten layer after filling and before recessing.

8. The method of claim 7, wherein the CMP process halted at the liner.

9. The method of claim 7, wherein the CMP process includes removing a portion of the dielectric is removed.

10. The method of claim 1, wherein recessing the tungsten layer includes at least one from the group consisting of: using a wet chemistry having a peroxide and using a reactive ion etch process.

11. The method of claim 1, wherein, after forming, over the liner, the metal layer that is predominantly made from the metal other than tungsten, the thin film dielectric layer is less than 40 nm.

12. The method of claim 1, further comprising, after forming, over the liner, the metal layer that is predominantly made from the metal other than tungsten, forming, an interconnect layer during a back end of line (BEOL) process.

13. An integrated circuit device comprising:
a substrate;
a plurality of electrical components on the substrate;
a thin film dielectric layer on the substrate; and
a set of interconnections electrically connecting the electrical components, each interconnection formed within a respective trench in the thin film dielectric layer and having:
a predominantly tungsten layer extending between two electrical components of the plurality of electrical components;
a liner over the tungsten layer and extending between the two electrical components; and
a metal layer that is over the tungsten layer, extends between the two electrical components and is predominantly made from a metal other than tungsten.

14. The device of claim 13, wherein the metal other than tungsten is copper.

15. The device of claim 13, further comprising a titanium/titanium nitride bilayer liner between the tungsten and the thin film dielectric layer.

16. The device of claim 13, wherein the liner is predominantly made from at least one of the group consisting of: tantalum, tantalum nitride, cobalt, ruthenium, titanium nitride, and manganese.

17. The device of claim 13, wherein the liner includes a layer of titanium nitride beneath a layer of tantalum nitride.

18. The device of claim 13, wherein the electrical components include Fin Field-Effect-Transistors.

19. The device of claim 13, wherein at least one trench of the set of interconnections has an upper width of less than 30 nm.

20. The device of claim 13, wherein, the thin film dielectric layer is less than 40 nm.

21. The device of claim 14, wherein a height ratio of the copper relative to tungsten is between 10:1 and 1:10.
